(19) United States
(12) Patent Application Publication
(10) Pub. No.: US 2019/0006918 A1
(43) Pub. Date: Jan. 3, 2019

(54) Brush Holder and DC Motor Provided with Same

(71) Applicant: Hitachi Automotive Systems Engineering, Ltd., Hitachinaka-shi, Ibaraki (JP)

(72) Inventors: Kenji KUNIYA, Hitachinaka-shi (JP); Yasuo SAITO, Hitachinaka-shi (JP); Takafumi SAITO, Hitachinaka-shi (JP); Keijirou OKABE, Hitachinaka-shi (JP)

(21) Appl. No.: 16/064,901

(22) PCT Filed: Dec. 2, 2016
(86) PCT No.: PCT/JP2016/085835

§ 371 Date: Jun. 21, 2018

(30) Foreign Application Priority Data
Dec. 25, 2015 (JP) 2015-252799

(51) Int. Cl. H02K 11/026; H02K 5/14; H03H 1/00; H01R 39/38

(52) U.S. Cl. CPC H02K 11/026; H01R 39/38; H03H 1/0007; H02K 5/148

(57) ABSTRACT

Provided is a direct current (DC) motor in which downsizing of the DC motor is possible while a choke coil and a capacitor are mounted on a brush holder to reduce radio noise. A DC motor includes a brush holder, in which the brush holder includes: a brush holder base formed of an insulating material; at least a pair of brushes that supplies power to a commutator; a spring that brings the brush in sliding contact with an outer circumferential portion of the commutator; and a choke coil and a capacitor for reducing radio noise, and the capacitor is provided on a surface of the brush holder, the surface being different from a surface on which the choke coil is provided.

### TECHNICAL FIELD

The present invention relates to a direct current (DC) motor.

### BACKGROUND ART

In a DC motor, radio noise is generated due to a contact state between a brush and a commutator or switching of current.

As a method for reducing the radio noise, it is common to mount a choke coil or a capacitor, or both the choke coil and the capacitor on a power supply circuit inside or outside the electric motor.

Since a radio noise reduction effect is increased when the choke coil and the capacitor are arranged on the power supply circuit near the brush, the choke coil and the capacitor are usually mounted on a brush holder. For example, a structure described in PTL 1 is known in which a choke coil is electrically connected between a plus electrode of a DC power supply and a first brush, and a choke coil is electrically connected between a minus electrode of the DC power supply and a second brush, and further a capacitor is electrically connected between the plus electrode and the minus electrode.

With this brush holder structure, the radio noise of the DC motor is reduced in accordance with frequency characteristics of a filter formed by the choke coil and the capacitor.

### CITATION LIST

### Patent Literature

PTL 1: JP 2007-267448 A

### SUMMARY OF INVENTION

### Technical Problem

In a case where the DC motor subjected to the radio noise reduction measure as described above is mounted on, for example, a vehicle, there is generally a limitation on a mounting space in the vehicle, and downsizing of the DC motor is essential.

However, in the above method, since the choke coil and the capacitor are mounted on the brush holder, downsizing of the brush holder is difficult, and further, downsizing of the DC motor is difficult. For downsizing of the brush holder and the DC motor, for example, if a choke coil and a capacitor respectively having small sizes and small capacities are used, the radio noise reduction effect weakens and the noise cannot be reduced in some cases.

An object of the present invention is to provide a DC motor in which downsizing of the DC motor is possible while a choke coil and a capacitor are mounted on a brush holder to reduce radio noise.

### Solution to Problem

To solve the above problems, for example, a configuration described in claims is adopted.

The present application includes a plurality of means for solving the above problems, and its examples include a DC motor including a brush holder, in which the brush holder includes: a brush holder base formed of an insulating material; at least a pair of brushes that supplies power to a commutator; a spring that brings each of the brushes into sliding contact with an outer circumferential portion of the commutator; and a choke coil and a capacitor for reducing radio noise, and the capacitor is provided on a surface of the brush holder, the surface being different from a surface on which the choke coil is provided.

### Advantageous Effects of Invention

According to the present invention, it is possible to provide a DC motor in which downsizing of the DC motor is possible while the choke coil and the capacitor necessary for reducing radio noise are mounted.

Problems, configurations, and effects other than those described above will be clarified from description of an embodiment below.

### BRIEF DESCRIPTION OF DRAWINGS

FIG. 1 is a cross-sectional view of a DC motor.

FIG. 2 is an exploded perspective view of a DC motor.

FIG. 3 is an exploded perspective view of a brush holder.

FIG. 4 is a perspective view of the brush holder (choke coil side).

FIG. 5 is a perspective view of the brush holder (capacitor side).

FIG. 6 is a mounting cross-sectional view of a connection terminal (before yoke insertion).

FIG. 7 is a mounting cross-sectional view of the connection terminal (after yoke insertion).

FIG. 8 is a simplified diagram of a radio noise reduction circuit configuration of an embodiment.

### DESCRIPTION OF EMBODIMENTS

Hereinafter, a brush holder structure according to an embodiment of the present invention will be described with reference to the drawings.

### Embodiment

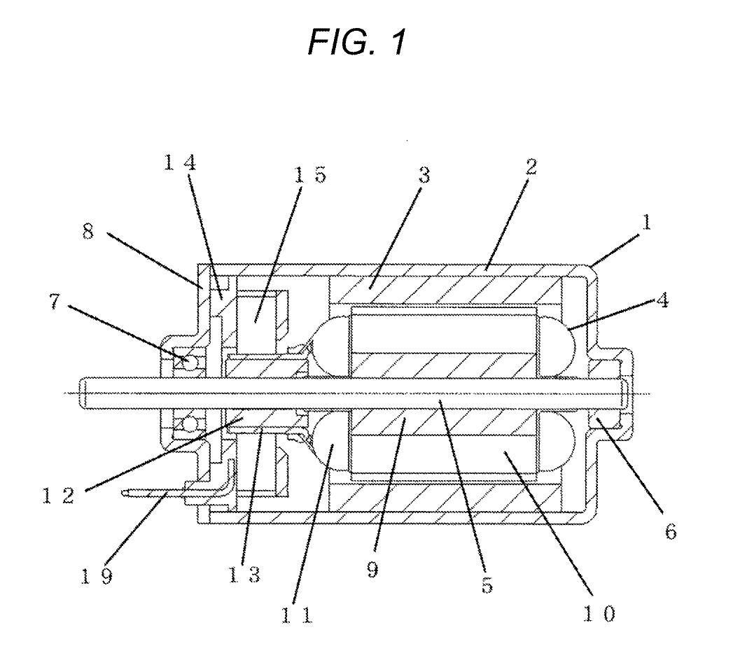

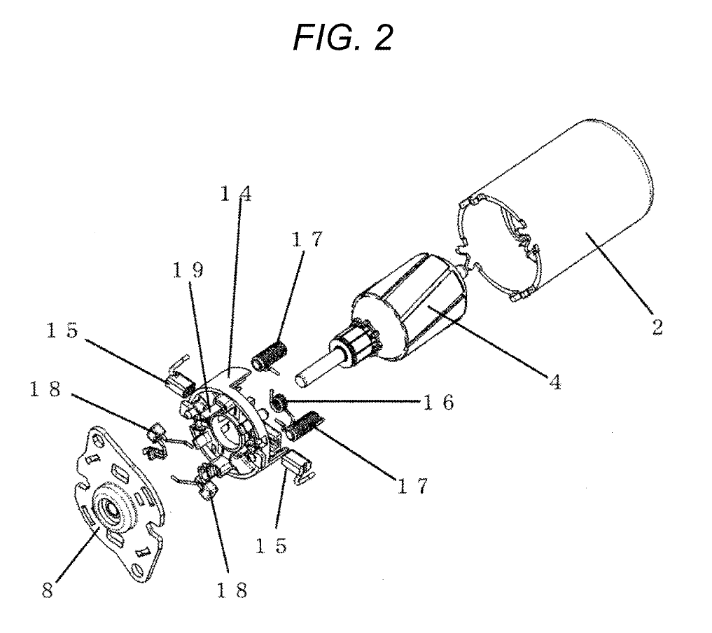

FIG. 1 is a cross-sectional view illustrating a structure of a general DC motor, and FIG. 2 is an exploded perspective view of a DC motor mounting a brush holder that is an embodiment of the present invention.

A DC motor 1 includes a yoke 2 forming a magnetic circuit while also serving as a motor case, and a plurality of magnets 3 is mounted on the inner surface of the yoke 2, and further, an armature 4 is accommodated in the inner side of the magnets 3 while holding an arbitrary gap from a magnet inner surface. The armature 4 is provided at the radial center with a shaft 5, and the shaft 5 is rotatably supported by the yoke 2 and a bracket 8 via a bearing 6 and a bearing 7. In the armature 4, an armature core 9 and a commutator 12 are fixed to the shaft 5, and a coil 11 is wound to straddle between a plurality of slots 10 formed in a circumferential direction outer circumferential portion of the armature core 9. The commutator 12 is formed in a cylindrical shape with an insulating material such as plastic and includes a plurality of commutator segments 13 made of a conductive material on the outer circumferential portion, and a part of each of the commutator segments 13 is electrically joined to the coil 11 wound between the slots 10.

Meanwhile, a brush holder 14 is accommodated inside the yoke 2, and on the brush holder 14, at least a pair of brushes that supplies power to the commutator segments 13 and a spring 16 are arranged, and further a choke coil 17 and a capacitor 18 are arranged for reducing radio noise. Each of the brushes 15 is electrically connected to an external power supply terminal 19 of the DC motor 1 and is brought into sliding contact with an outer circumferential surface of each of the commutator segments 13 by pressing force of the spring 16 held by the brush holder 14, and the power is supplied to the coil 11 via each of the commutator segments 13.

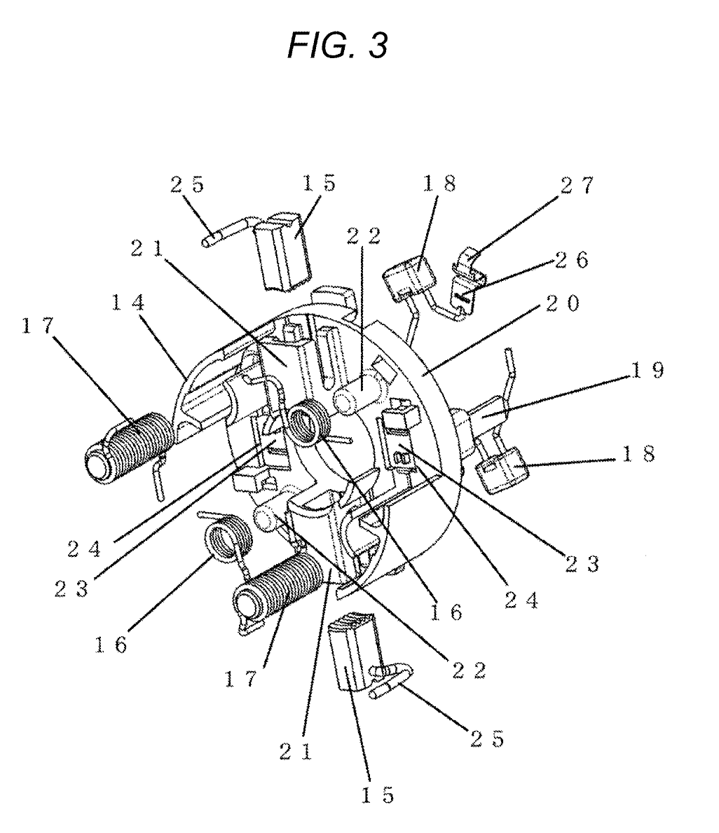

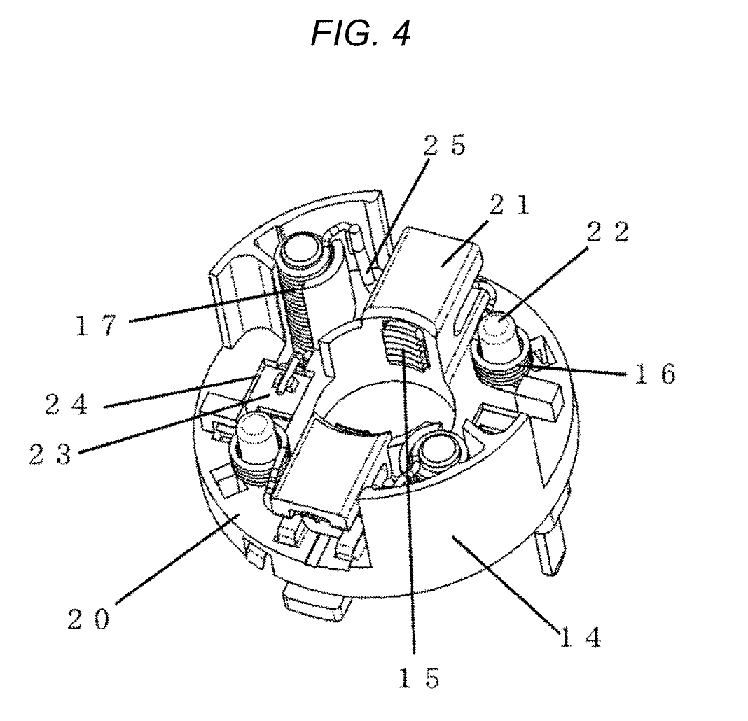

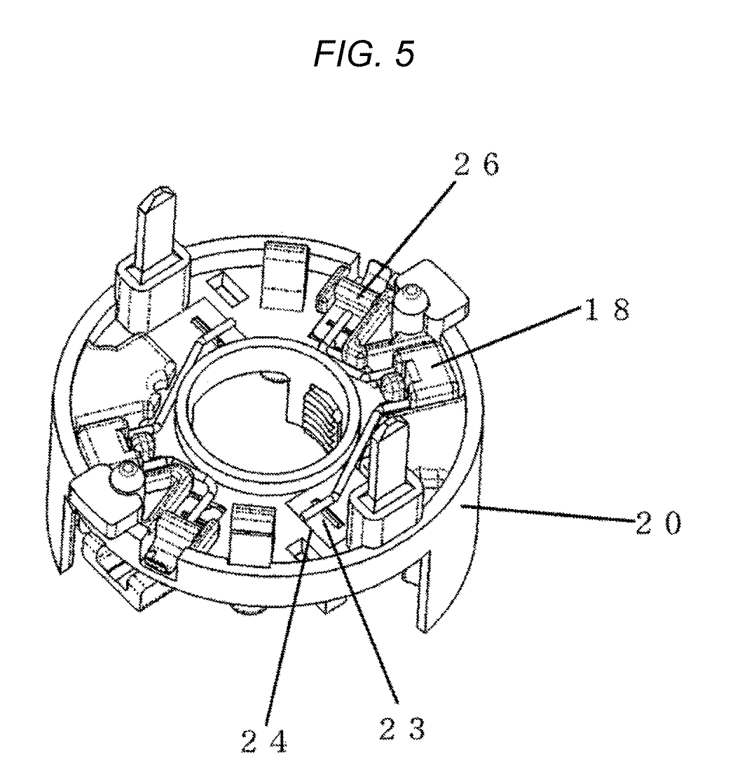

FIGS. 3, 4, and 5 are perspective views each illustrating the brush holder that is the embodiment of the present invention.

In the brush holder 14, on a brush holder base 20 formed in a substantially circular shape with an insulating material such as plastic, a brush box 21 that holds each of the brushes and a spring holder 22 that holds the spring 16 are integrally molded or formed with a method such as assembly with separate parts, and each of the brushes 15 that supplies power to each of the commutator segments 13 and the spring 16 that brings each of the brushes 15 into sliding contact with the outer circumferential portion of each of the commutator segments 13 are arranged on the brush holder base 20. Further, the choke coil 17 and the capacitor 18 for reducing radio noise are respectively arranged on different surfaces of the brush holder base 20.

Inside the brush holder base 20, a power supply terminal 23 is included to be connected to the choke coil 17 and the capacitor 18 with a method such as insert molding, and an opening 24 is provided in both surfaces of the brush holder base 20 so that a part of the power supply terminal 23 is exposed on both surfaces of a mounting surface of the choke coil 17 and a mounting surface of the capacitor 18, of the brush holder base 20.

In the present embodiment, the power supply terminal 23 included inside the brush holder base 20 and the external power supply terminal 19 of the DC motor 1 are integrally formed; however, the power supply terminal 23 and the external power supply terminal 19 may be formed, as separate parts, with joining or the like.

In the choke coil 17, one end is connected to the power supply terminal 23 at the opening 24 of the brush holder base 20, and the other end is connected to a lead wire 25 of each of the brushes 15, whereby the power supply terminal 23 and each of the brushes 15 are electrically connected together via the choke coil 17, and further the power is supplied to the coil 11 via each of the commutator segments 13 that is in sliding contact with each of the brushes 15.

In the present embodiment, the choke coil 17 and each of the brushes 15 are arranged on the same surface of the brush holder base 20; however, the choke coil 17 and each of the brushes 15 may be respectively arranged on different surfaces of the brush holder base 20.

The capacitor 18 is arranged on a surface of the brush holder base 20, the surface being different from a surface on which the choke coil 17 is arranged, and one end is connected to the power supply terminal 23 at the opening 24 of the brush holder base 20, and the other end is connected to a connection terminal 26 fixed to the brush holder base 20 and is electrically connected to the yoke 2 via the connection terminal 26.

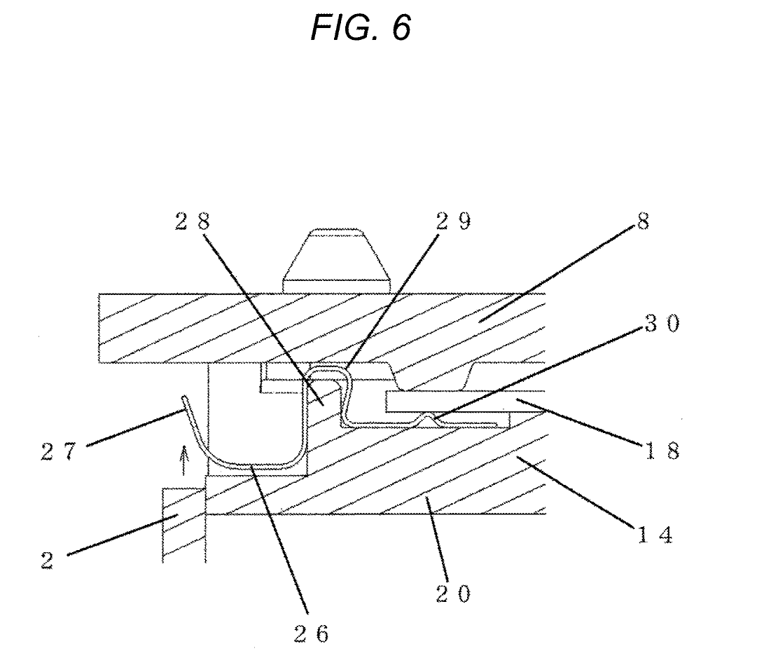

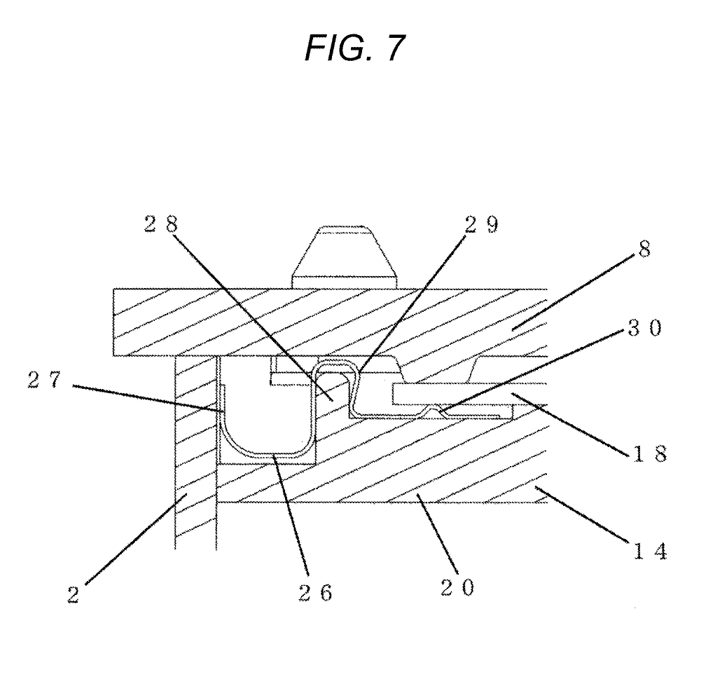

FIGS. 6 and 7 are mounting cross-sectional views of the connection terminal mounted to the brush holder that is the embodiment of the present invention, and FIG. 6 illustrates a state before yoke insertion, and FIG. 7 illustrates a state after yoke insertion.

The connection terminal 26 is formed by, for example, forming a thin plate of a conductive material such as copper, and includes a claw portion 27 to be brought into contact with the yoke 2, a substantially valley-shape formed portion 29 that is a fixing portion to the brush holder base 20, and a bent portion 30 to be connected to the capacitor 18.

As illustrated in FIG. 6, as a method for fixing the connection terminal 26 to the brush holder base 20, a wall-shaped protruding portion 28 is provided on the brush holder base 20, and the substantially valley-shape formed portion 29 provided in the connection terminal 26 is fitted into the wall-shaped protruding portion 28 to be fixed. The substantially valley-shape formed portion 29 provided in the connection terminal 26 is formed such that the depth side of the wall-shaped protruding portion 28 narrows when the connection terminal 26 is mounted to the wall-shaped protruding portion 28 provided on the brush holder base 20, and the connection terminal 26 has a structure that sandwiches the wall-shaped protruding portion 28 of the brush holder base 20, which is a contrivance that makes it easy to fit and makes it difficult to come off.

In addition, as illustrated in FIG. 7, the claw portion 27 for bringing the connection terminal 26 into contact with the yoke 2 has a spring function, and the claw portion 27 has a structure that generates a radial load toward the yoke 2 side, and the contact state between the connection terminal 26 and the yoke 2 is maintained by spring force of the claw portion 27 when the brush holder 14 is arranged in the yoke 2. Meanwhile, the bent portion 30 having a spring function is provided at a connection of the capacitor 18 of the connection terminal 26, and the bent portion 30 generates a load to press the capacitor 18 against the bracket 8, and the capacitor 18 is sandwiched between the bracket 8 and the connection terminal 26 by the spring force of the bent portion 30, and the contact state is maintained while the connection terminal 26 and the capacitor 18 are electrically connected together.

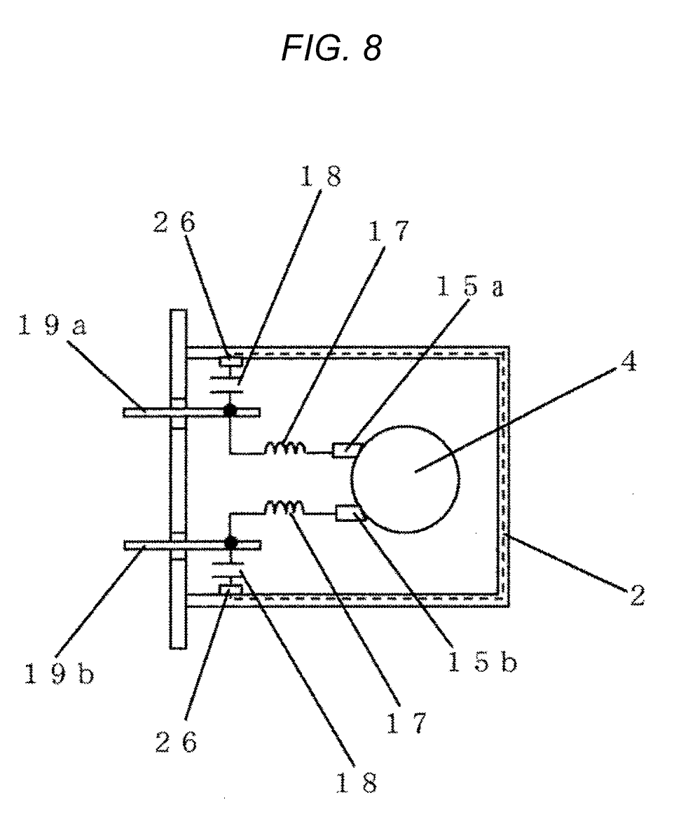

FIG. 8 illustrates a simplified diagram of a radio noise reduction circuit configuration according to the embodiment of the present invention.

The choke coil 17 is electrically connected between a plus terminal 19a of the external power supply terminal 19 and a first brush 15a, and another choke coil 17 is electrically connected between a minus terminal 19b of the external power supply terminal 19 and a second brush 15b, whereby a noise filter is formed between the external power supply terminal 19 and each of the brushes 15. Further, the capacitor 18 is electrically connected between the plus terminal 19a of the external power supply terminal 19 and the yoke 2 via the connection terminal 26, and another capacitor 18 is electrically connected between the minus terminal 19b of the external power supply terminal 19 and the yoke 2 via another connection terminal 26, whereby a noise filter is formed between the plus terminal 19a and the minus terminal 19b of the external power supply terminal 19 via the capacitor 18 and the yoke 2.

In this way, the choke coil 17 and the capacitor 18 are respectively arranged on different surfaces of the brush holder 14, and the power supply terminal 23 to be connected to the choke coil 17 and the capacitor 18 is included inside the brush holder base 20, whereby downsizing of the brush holder 14 is possible, and further, downsizing of the DC motor 1 is possible, while the filter that reduces radio noise is mounted.

Note that, the present invention is not limited to the embodiment described above, and includes various modifications. For example, the embodiment described above has been described in detail for describing the present invention clearly, and is not necessarily limited to that including all the configurations described. For a part of the configuration of the embodiment, it is possible to add, remove, and replace another configuration.

### REFERENCE SIGNS LIST

1 DC motor

2 yoke

3 magnet

4 armature

5 shaft

6, 7 bearing

8 bracket

9 armature core

10 slot

11 coil

12 commutator

13 commutator segment

14 brush holder

15 brush

15a first brush

15b second brush

16 spring

17 choke coil

18 capacitor

19 external power supply terminal

19a plus terminal

19b minus terminal

20 brush holder base

21 brush box

22 spring holder

23 power supply terminal

24 opening

25 lead wire

26 connection terminal

27 claw portion

28 protruding portion

29 substantially valley-shape formed portion

30 bent portion

1. A direct current (DC) motor comprising
a brush holder, wherein
the brush holder includes:
a brush holder base formed of an insulating material;
at least a pair of brushes that supplies power to a commutator;
a spring that brings each of the brushes into sliding contact with an outer circumferential portion of the commutator; and
a choke coil and a capacitor for reducing radio noise, and
the capacitor is provided on a surface of the brush holder, the surface being different from a surface on which the choke coil is provided.

2. The DC motor according to claim 1, wherein
a power supply terminal that connects one end of the capacitor and one end of the choke coil together is included inside the brush holder base of the brush holder,
an opening for exposing the power supply terminal on both surfaces of the brush holder is provided in the brush holder base of the brush holder, and
the one end of the capacitor and the one end of the choke coil are connected together via the power supply terminal exposed through the opening.

3. The DC motor according to claim 1, wherein
a connection terminal that electrically connects another end of the capacitor and a yoke together is provided on the brush holder.

4. The DC motor according to claim 3, wherein
the connection terminal includes a claw portion having a spring function, and
the claw portion generates a radial load toward the yoke's side.

5. The DC motor according to claim 3, wherein
the connection terminal has a spring function in a connection of the capacitor,
the spring function generates a load to press the capacitor against a bracket, and
the connection terminal and the capacitor are connected together by the spring function.
